(19) United States
(12) Patent Application Publication
(10) Pub. No.: US 2013/0248977 A1
(43) Pub. Date: Sep. 26, 2013

(54) NON-VOLATILE SEMICONDUCTOR STORAGE DEVICE AND MANUFACTURING METHOD OF THE SAME

(71) Applicant: KABUSHIKI KAISHA TOSHIBA, Tokyo (JP)

(72) Inventors: Shinji MORI, Kanagawa (JP); Jun FUJIKI, Kanagawa (JP); Kiyotaka MIYANO, Tokyo (JP)

(73) Assignee: KABUSHIKI KAISHA TOSHIBA, Tokyo (JP)

(21) Appl. No.: 13/791,727

(22) Filed: Mar. 8, 2013

(30) Foreign Application Priority Data
Mar. 23, 2012 (JP) P2012-068437

(51) Int. Cl. H01L 29/792; H01L 29/66

(52) U.S. Cl. CPC H01L 29/7926; H01L 29/66833
USPC 257/326; 438/268

(57) ABSTRACT

A non-volatile semiconductor storage device according to one embodiment of the present application has a memory cell array that includes at least one memory string, a first select transistor, and a second select transistor on a substrate in a lattice form. The first select transistor is electrically connected to a first end of the memory string. The second select transistor is electrically connected to a second end of the memory string. The memory string includes a columnar portion. Multiple memory cells are formed in the columnar portion by multiple conductive layers, multiple insulating layers, a first insulating layer, a charge accumulation layer, a second insulating layer, and a memory channel layer, and are serially connected. The memory channel layer comprises silicon germanium doped with phosphorus.

### CROSS-REFERENCE TO RELATED APPLICATION

This application is based upon and claims the benefit of priority from Japanese Patent Application No. 2012-068437, filed Mar.23, 2012, the entire contents of which are incorporated herein by reference.

### FIELD

Embodiments described herein relate a non-volatile semiconductor storage device and its manufacturing method.

### BACKGROUND

A type of non-volatile semiconductor storage device includes the NAND type flash memory. Conventionally, NAND type flash memories have experienced an increase in capacity and a reduction in bit cost through refinement of the silicon process technology, e.g., by miniaturization of feature size. However, further refinement of the process technology is extremely difficult and tends to increase the manufacturing costs as well. For this reason, forming a three-dimensional memory cell array by stacking multiple stages of planar structures of memory cell arrays that have been formed two-dimensionally can be envisioned. However, the frequency of lithography techniques at the minimum line width increases as additional planar structures are stacked. For this reason, even if the memory cell array is made as a three-dimensional structure, bit cost reduction cannot be achieved as expected.

Recently, the BiCS (Bit-Cost Scalable) technique has been developed. The technique reduces the bit cost, along with increasing the number of lamination layers of the memory cell array, and a NAND type flash memory that uses this technique has been developed.

With the BiCS technique, a memory cell array is formed as follows. Multiple conductive layers are laminated with insulating layers as intermediaries. In the memory hole that penetrates these laminate structures, a conductive material channel layer is installed via a charge accumulation layer that is sandwiched between the insulating layers. The laminated multiple conductive layers act as the control gate, and the charge accumulation layer acts as the floating gate. That is, the memory cell is formed by a conductive layer, a charge accumulation layer sandwiched by the insulating layers, and a conductive material channel layer. This memory cell is series-connected in the lamination direction within the memory hole and the memory string is formed. With multiples of this memory string being arrayed in a horizontal plane, a three-dimensional memory cell is formed.

With the BiCS flash memory, unlike with a two-dimensional flash memory, a conductive material channel layer made from Si is formed on the insulating layer of the charge accumulation layer. For this reason, the channel layer is not monocrystalline, but, rather, is formed from amorphous silicon or polysilicon. As a result, the channel resistance in the memory cell is high, and the drive current is low. In order to increase the read speed of the flash memory, there is a need to increase the drive current and provide a low resistance in the channel layer of a BiCS flash memory.

### DESCRIPTION OF THE DRAWINGS

FIG. 1 is a schematic perspective view of the principal components of the non-volatile semiconductor storage device according to a first embodiment.

FIG. 2 is a schematic cross-sectional diagram of the principal components of the non-volatile semiconductor storage device according to the first embodiment.

FIG. 3 is a graph that shows the effect of the non-volatile semiconductor storage device according to the first embodiment.

FIG. 4 is a graph that shows the effect of the non-volatile semiconductor storage device according to the first embodiment.

FIG. 5A, FIG. 5B and FIG. 5C are schematic cross-sectional diagrams that show a portion of the manufacturing process of the non-volatile semiconductor storage device according to an embodiment.

FIG. 6A and FIG. 6B are schematic cross-sectional diagrams that show a portion of the manufacturing process of the non-volatile semiconductor storage device according to an embodiment.

FIG. 7A and FIG. 7B are schematic cross-sectional diagrams that show a portion of the manufacturing process of the non-volatile semiconductor storage device according to an embodiment.

FIG. 8A and FIG. 8B are schematic cross-sectional diagrams that show a portion of the manufacturing process of the non-volatile semiconductor storage device according to an embodiment.

FIG. 9 is a schematic perspective view of the principal components of the non-volatile semiconductor storage device according to another embodiment.

### DETAILED DESCRIPTION

Embodiments of the present invention provide a non-volatile semiconductor storage device with a low channel resistance in a three-dimensional memory cell array.

Embodiments of the present invention will be described with reference to the figures. The figures used in the description of the embodiments are schematic in order to simplify the descriptions. The actual implementations of the forms, dimensions, and magnitude relationships of the elements are not necessarily limited to how they are shown in the figures, and may be changed within the bounds of achieving the effects of the present invention.

The non-volatile semiconductor storage device according to one embodiment of the present invention is equipped with a memory cell array that includes multiple memory strings, first select transistors, and second select transistors on a substrate in a lattice form. The memory string includes a columnar part in which multiple memory cells that can electrically read and write memory, are electrically series-connected along a first direction that is perpendicular to the substrate. The first select transistor includes a first channel layer that is controlled by the first select gate and one end of the first channel layer is electrically connected to one end of the memory string. The second select transistor includes a second channel layer that is controlled by the second select gate and one end of the second channel layer is electrically connected to the other end of the memory string on the opposite side of the one end. The columnar part of the memory string includes multiple conductive layers, multiple insulating layers, a first insulating layer, a charge accumulation layer, a second insulating layer, and a memory channel layer. Multiple conductive layers and multiple insulating layers are formed on the substrate and are alternately laminated along the first direction. The first insulating layer is provided along the inner circumference on the inner wall of the memory hole that penetrates the multiple conductive layers and the multiple insulating layers, and extends along the first direction. The charge accumulation layer is formed along the inner circumference on the inner wall of the first insulating layer and extends along the first direction. The second insulating layer is formed along the inner circumference on the inner wall of the charge accumulation layer and extends along the first direction. The memory channel layer is formed along the inner circumference on the inner wall of the second insulating layer and extends along the first direction, and is formed by SiGe which includes phosphorus.

Multiple memory cells are formed by multiple conductive layers, a first insulation layer, a charge accumulation layer, a second insulating layer, and a memory channel layer. The memory channel layer is electrically connected to one end of the first channel layer of the first select transistor on one end of the memory string and electrically connected to one end of the second channel layer of the second select transistor on the other end of the memory string.

### First Embodiment

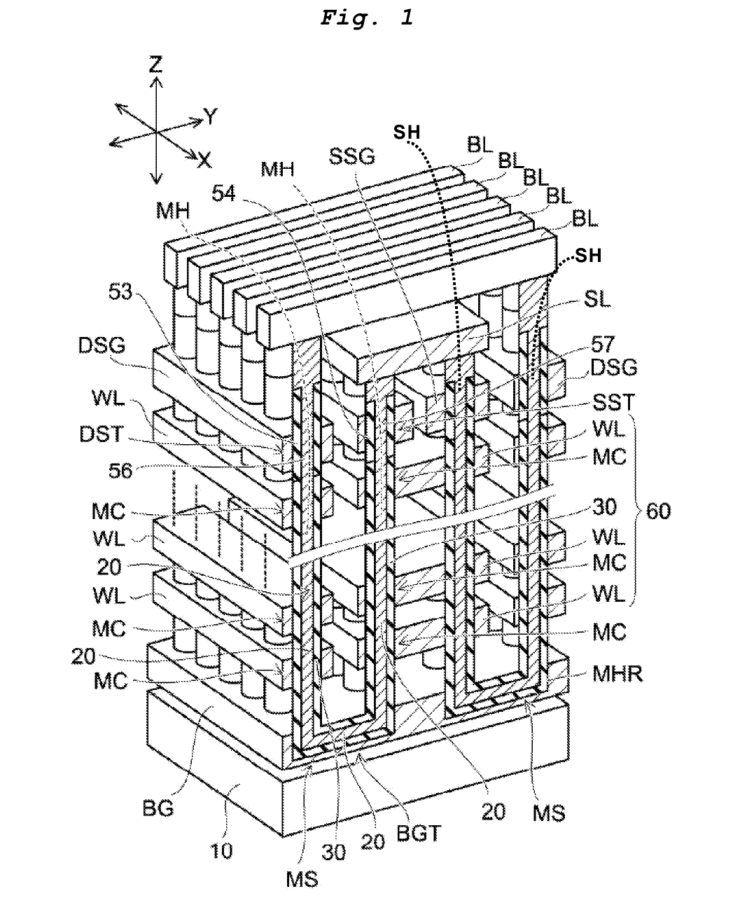

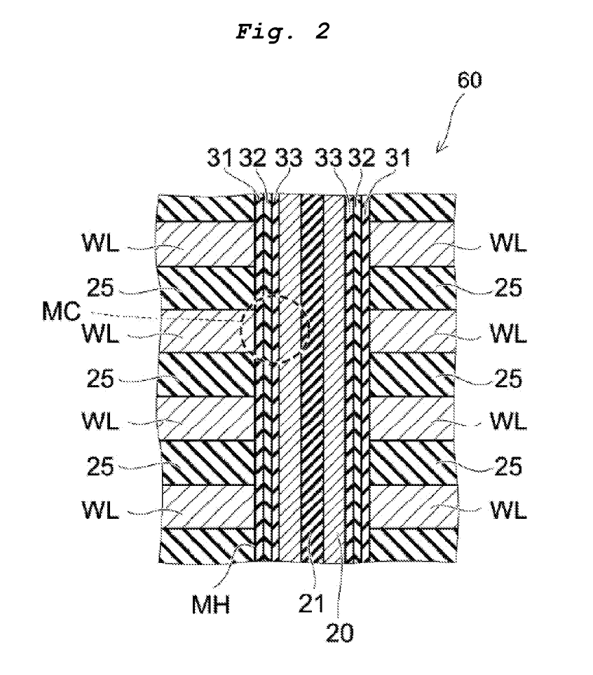

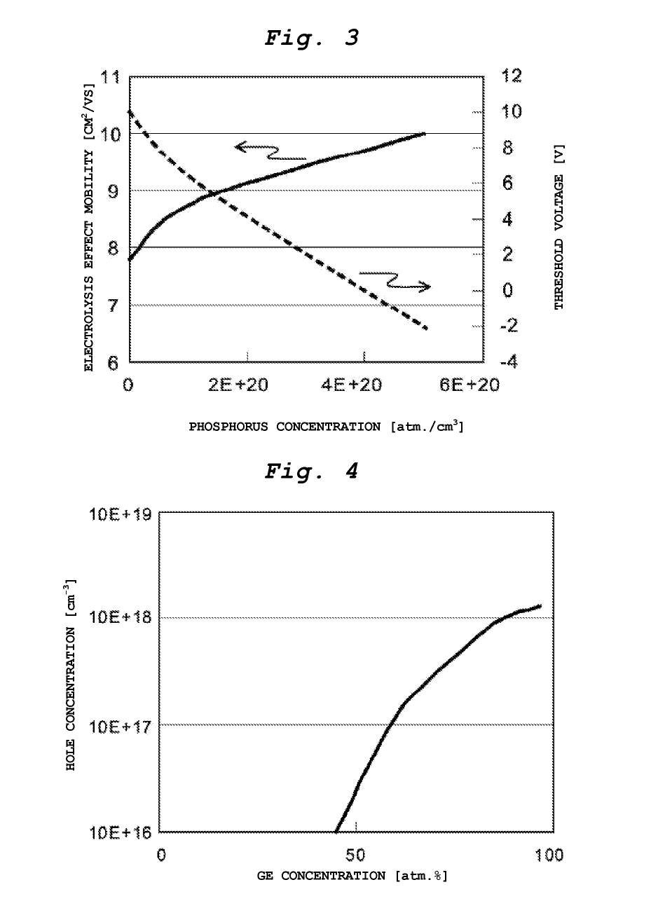

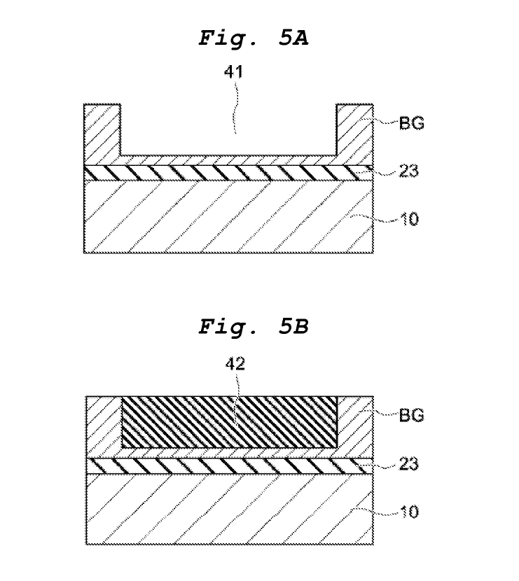

A NAND type flash memory that is a non-volatile semiconductor storage device according to the first embodiment of the present invention is described, using FIG. 1 through FIG. 4. FIG. 1 is a schematic perspective view of the principal parts of the non-volatile semiconductor storage device according to the first embodiment. FIG. 2 is a schematic cross-sectional diagram of the principal parts of the non-volatile semiconductor storage device according to the first embodiment and is a schematic cross-section diagram of a part of the memory string shown in FIG. 1. FIG. 3 and FIG. 4 are graphs that explain the effect of the non-volatile semiconductor storage device according to the first embodiment.

As shown in FIG. 1, the non-volatile semiconductor storage device according to the present embodiment has a memory cell array that includes multiple U-shaped memory strings MS, drain side select transistors (first select transistor) DST, and source side select transistors (second select transistor) SST on a substrate 10 in a lattice form. The cross-section in the X-direction of the perspective view of FIG. 1 is the cross-section of a unit cell that includes a pair of U-shaped memory strings. These unit cells are arranged in a lattice form in the memory cell. Meanwhile, for the sake of convenience for the description, in the horizontal plane on the substrate 10, using the X-direction and the Y-direction that is orthogonal to this, the direction that is perpendicular to the substrate shall be the Z-direction. Also in FIG. 1, the interlayer dielectric film and the insulating layer are omitted for clarity in the drawing.

On the substrate 10, a conductive layer that is used as the back gate of the back gate transistor BGT mentioned below (henceforth, the back gate layer BG) is provided on an interlayer dielectric film, not shown in the drawing. On the back gate layer BG, as shown in FIG. 2, is formed a laminate (layered structure) that has alternate layer stacks of multiple conductive layers WL (word lines) and multiple insulating layers 25 in the Z-direction, within or on an interlayer dielectric film not shown in the drawing. The back gate layer BG and the multiple conductive layers WL are, for example, formed by conductive polysilicon, but are not limited to this. The conductivity type of the polysilicon can be an n-type or a p-type. The insulating layer 25 is, for example, formed from silicon dioxide (SiO₂), but can also be formed from other insulating bodies, such as silicon nitride (SiN) or silicon oxynitride (SiON).

The laminate 60 is divided into multiple blocks that extend in the X-direction in a striped (layered) fashion. Provided between each of the blocks of the multiple laminates 60 are interlayer dielectric films not shown in the figure. Each of the multiple conductive layers WL in the laminate 60 is divided into multiple parts in the Y-direction and are disposed extending in the X-direction in strips. That is, each block of the laminate 60 includes multiple spaced conductive layers WL that are laminated in the Z-direction.

In each block of the laminate 60 are provided multiple memory holes MH that penetrate the laminate 60 along the X-direction. The diameter of the memory hole MH is, for example, 56 nanometers (nm). The memory hole MH is coupled to another memory hole MH that extends into the back gate layer BG and is formed in a block of a laminate 60 that is adjacent in the Y-direction, in the back gate layer BG by a coupling hole region MHR. As a result, memory holes MH that are adjacent to each other in the Y-direction form one U-shaped memory hole.

Referring to FIG. 2, a first insulating layer 31 is formed along the inner circumference on the inner wall of each memory hole MH that penetrates the laminate 60, and is disposed so that it extends along the Z-direction. The first insulating layer 31 is further formed along the inner circumference on the inner wall of the coupling hole region MHR (omitted in the figure). That is, it is provided on the entire surface on the inner wall of the U-shaped hole. Silicon dioxide, for example, is used for the first insulating layer 31.

A charge accumulation layer 32 is formed in each memory hole MH, along the inner circumference on the inner wall of the first insulating layer 31 and so that it extends along the Z-direction. The charge accumulation layer 32 is further provided in the coupling hole region MHR (omitted in the figure) along the inner circumference on the inner wall of the first insulating layer 31. That is, it is provided in the U-shaped hole on the entire surface on the inner wall of the first insulating layer 31. The charge accumulation layer 32 can be any material that can accumulate a charge locally by trapping electrons in the part where the voltage is applied. For example, silicon nitride can be used for the charge accumulation layer 32.

A second insulating layer 33 is formed in each memory hole MH along the inner circumference on the inner wall of the charge accumulation layer 32 so that it extends along the Z-direction. The second insulating layer 33 is further provided in the coupling hole region MHR (omitted in the figure) along the inner circumference on the inner wall of the charge accumulation layer 32. That is, it is provided in the U-shaped hole on the entire surface on the inner wall of the charge accumulation layer 32. For the second insulating layer 33, as with the second insulating layer 31, for example, silicon dioxide can be used. The combined film thickness of the first insulating layer 31, the charge accumulation layer 32, and the second insulating layer 33 is, for example, 17.5 nm.

A memory channel layer 20 is formed in each memory hole MH along the inner circumference on the inner wall of the second insulating layer 33 so that it extends along the Z-direction. The memory channel layer 20 is further provided in the coupling hole region MHR (omitted in the figure), along the inner circumference on the inner wall of the second insulating layer 33. That is, it is provided in the U-shaped hole, on the entire surface of the inner wall of the second insulating layer 33. The memory channel layer 20 is a silicon germanium (SiGe) layer including phosphorus (P). The film thickness of the memory channel 20 is, for example, 7 nm.

The memory channel layer 20 further includes, in the memory hole MH, a SiN layer 21 as a central layer that extends in the Z-direction. The memory channel layer 20 also includes a SiN layer 21 provided in the coupling hole region MHR (omitted in the figure). That is, in the entirety of the U-shaped hole, the memory channel layer 20 has an internal SiN layer 21. The diameter of the SiN layer is 7 nm. Alternatively, a cavity can be formed in place of the SiN layer 21. The memory channel layer 20 can also be formed only with the memory channel layers 20 on the inner side of the second insulating layer 33 inside the U-shaped hole, without including a SiN layer 21 or a cavity. In this case, the diameter of the memory channel layer 20 is 21 nm.

Here, as shown by the dashed line in FIG. 2, a memory cell MC is formed by the conductive layer WL, and the first insulating layer 31, the charge accumulation layer 32, the second insulating layer 33, and the memory channel layer 20, which are each provided inside the memory hole MH. The memory cell MC is a memory transistor that includes a conductive layer WL as the control gate electrode and a charge accumulation layer 32 as the floating gate electrode. By provided a first insulating layer 31, a charge accumulation layer 32, a second insulating layer 33, and a memory channel layer 20 in the memory hole MH formed in one block of the laminate 60 (henceforth to be called the first block), as described above, a columnar part in which multiple memory cells MC are electrically-connected in series in the Z-direction is formed. This will be referred to as the first columnar part.

In a different memory hole MH that is located in a different block that is adjacent to the block of this laminate 60 (henceforth to be called the second block), are also provided a first insulating layer 31, a charge accumulation layer 32, a second insulating layer 33, and a memory channel layer 20. This forms a different columnar part including multiple different memory cells MC that are electrically series connected in the Z-direction. This will be referred to as the second columnar part.

The two memory holes MH form one U-shaped hole as shown in FIG. 1 and described above. For this reason, the first columnar part and the second columnar part (another columnar part) are electrically connected by a first insulating layer, a charge accumulation layer 32, a second insulating layer 33, and a memory channel layer 20 formed in the coupling hole region MHR of the U-shaped hole. A back gate transistor BGT is formed from a back gate layer BG, in which the coupling hole region MHR is formed, and a first insulating layer, a charge accumulation layer 32, a second insulating layer 33, and a memory channel layer 20 are formed in the coupling hole region MHR. That is, the first columnar part and the second columnar part are electrically connected by the channel part of the back gate transistor BGT on the substrate 10 side. When a voltage exceeding the threshold value is applied to the back gate BG, a channel is formed in the part that opposes the back gate BG in the memory channel layer 20, and the first columnar part and the second columnar part are electrically connected. As a result, a U-shaped memory string MS is composed of a first columnar part, back gate transistor BGT, and a second columnar part.

On the conductive layer WL in the uppermost layer on the side that is opposite of the substrate 10, in the first columnar part of the memory string MS, a drain side select gate DSG is provided within an interlayer dielectric film (not shown in the figure). The drain side select gate DSG, as with the conductive layer WL, is formed of conductive polysilicon. The drain side select gate DSG has a hole SH that is located in the position that corresponds to the upper part of the memory hole MH of the first columnar part. In this hole is provided a channel layer 56 within a gate insulating film 53. The channel layer 56 is, for example, formed from polysilicon. Also, the gate insulating film 53 may be, for example, formed by silicon dioxide. The drain side select transistor DST includes the drain side select gate DSG, the gate insulating film 53, and the channel layer 56. The drain side select gate DSG functions as the gate electrode and controls the current of the channel layer 56. When a voltage exceeding the threshold value is applied to the drain side select gate DSG, a channel is formed in the part that opposes the drain side select gate DSG of the channel layer 56 and the drain side select transistor DST is turned ON.

One end of the channel layer of the drain side select transistor DST is electrically connected to one end of the memory channel layer 20 and the conductive layer WL in the uppermost layer of the first columnar part of the memory string MS. The other end of the channel layer 56 of the drain side select transistor DST is electrically connected to a bit line BL, as shown in FIG. 1. The bit lines BL are provided on the drain side select gate DSG on the interlayer dielectric film (not shown) and extends in the Y-direction perpendicular to the conductive layer WL.

The second columnar part of the memory string MS has a conductive layer WL that makes up a block (second block) of the laminate 60 that is different from the first columnar part. On the conductive layer WL on the uppermost layer of this second columnar part is formed a source side select gate layer SSG on an interlayer dielectric film that is not shown in the figure. The source side select gate layer SSG, like the conductive layer WL, is formed from conductive polysilicon. The source side select gate layer SSG has a hole SH that is located in a position that corresponds to the upper part of the memory hole MH of the second columnar part. In this hole SH is formed a channel layer 57 within a gate insulating film 54. The channel layer 57 is, for example, formed from polysilicon. Also, the gate insulating film 54 is, for example, formed from silicon dioxide. The source side select transistor SST includes the source side select gate layer SSG, the gate insulating film 54, and the channel layer 57. The source side select gate layer SSG functions as the gate electrode and controls the current of the channel layer 57. When a voltage exceeding the threshold value is applied to the source side select gate layer SSG, a channel is formed in the part that opposes the source side select gate layer of the channel layer 57, and the source side select transistor SST is turned ON.

One end of the channel layer of the source side select transistor SST is electrically connected to the other end of the memory channel layer 20 in the conductive layer WL in the uppermost layer of the second columnar part of the memory string MS. The other end of the source side select transistor SST is electrically connected to the source line SL, as shown in FIG. 1. The source line SL is disposed on the source side select gate layer SSG surrounded by the interlayer dielectric film and extends in the X-direction parallel to the conductive layer WL.

As shown above, the non-volatile semiconductor storage device according to the present embodiment is equipped with a memory cell array that includes multiple U-shaped memory strings MS, drain side select transistors DST, and source side select transistors SST on the substrate 10 in a lattice form (that is, arranged in the X-direction and the Y-direction). On one end of the U-shaped memory string MS, the memory channel layer 20 is electrically connected to the bit line BL via the channel layer 56 of the drain side select transistor DST. On the other end of the U-shaped memory string, the memory channel 20 is electrically connected to the source line SL via the channel layer 57 of the source side select transistor SST. The multiple conductive lines WL function as the word line. The memory string MS acts as the NAND type flash memory.

In the actions of read, write, and erase, etc., the memory string MS is selected by the bit line BL, the drain side select transistor DST, and the source side select transistor SST. Actions such as read, write, and erase are carried out in the selected memory string MS, on the individual memory cell MC by the word line WL. Meanwhile, by applying a voltage that exceeds the threshold level to the back gate layer BG of the back gate transistor BGT and turning the back gate transistor BGT ON, the first columnar part and the second columnar part in the memory string MS are electrically connected.

In the non-volatile semiconductor storage device according to the present embodiment, information is written in the following manner. By applying a high voltage for writing to the word line (conductive layer WL) that corresponds to the selected memory cell MC, electrons are trapped in the charge accumulation layers 32 of the selected memory cells. Electrons are trapped in the charge accumulation layers 32 only in the parts between the conductive layer WL of the selected memory cell MC and the memory channel layer 20. In the memory cell MC, if a gate voltage that exceeds the threshold level is applied to the conductive layer WL, a channel is formed in the part of the memory channel layer 20 that opposes the word line. As a result, the memory cell MC turns ON. In the memory cell MC where electrons are trapped in the charge accumulation layer, the threshold level of the gate voltage for forming this channel rises. Using the magnitude relation of this threshold level, the state in which electrons are trapped in the charge accumulation layer of the memory cell MC corresponds to the logical value “0”, and the state in which electrons do not exist corresponds to the logical value “1”. That is, the state with a high threshold level corresponds to “0” and the state with a low threshold level corresponds to “1”. The threshold level of the former shall be Vₜₕ(0) and the threshold level of the latter shall be Vₜₕ(1).

Each memory cell of the columnar part in the memory string connects each other's channels when they are mutually ON and are electrically connected. Therefore, the current that is applied to the memory channel layer 20 of the memory string MS is determined by the logical value of the NAND, in respect to the voltage signal that is applied to each word line (conductive layer WL) of the memory string MS. When the selected memory cell is to be read, a voltage that is greater than Vₜₕ(0) and less than Vₜₕ(1) is applied to the word line that corresponds to the selected memory cell MC, and a voltage that is greater than Vₜₕ(0) is applied to the other word lines. If electrons are trapped by the selected memory cell, a current is not applied to the channel layer in the memory string MS, and if electrons are not trapped, a current is applied. With this, information can be read from each memory cell MC in the memory string MS that is selected by the select transistor.

Therefore, in the non-volatile semiconductor storage device according to the present embodiment, the current that is applied to the memory string MS is a higher current than is provided in the conventional devices, in order to speed up the read operation. Conversely, the ON resistance of the memory channel layer 20 in the memory string MS less than is provided in the conventional devices.

Generally, the memory channel layer 20 is formed by depositing amorphous silicon on the inner wall in the memory hole MH using a CVD (Chemical Vapor Deposition) method. However, when amorphous silicon is film formed undoped, it has a high resistance due to mobility being extremely low, and so the current that is applied to the memory string MS is extremely low. For this reason, if the number of memory cells in the memory string is increased by increasing the number of layers of the word line of the laminate 60, the current value further decreases, which suppresses an increase in the bit density.

The reason why the mobility of amorphous silicon is high is, since it is noncrystalline, electrons are scattered inside the film. The greater the crystallinity, the higher the mobility, so as a memory channel layer, polysilicon may be used. However, film forming of polysilicon using the CVD method, as compared to amorphous silicon, results in poor planarity. For this reason, if a polysilicon film is formed in the memory hole MH, the memory channel layer 20 is formed with an uneven thickness, which generates an undesirable variability in the performance characteristics. However, by applying a heat treatment after film forming the amorphous silicon on the inner wall of the memory hole MH, recrystallization is induced, and it is changed from amorphous silicon to polysilicon. Nevertheless, this is not enough to make the grain diameter of the polysilicon crystals sufficiently large, and mobility is still low.

FIG. 3 shows the phosphorus concentration dependence of the mobility of the electrons in the channel layer and the threshold level of the gate voltage in a MOSFET (Metal Oxide Semiconductor Field Effect Transistor) that includes in its channel layer, a material that adds phosphorus to amorphous silicon, which is then recrystallized by applying heat treatment. The field effect mobility in the figure is calculated by the formula (1) below. Here, Gₘ=∂ld/∂V_{g}, W is the channel width, L is the channel length, Cᵢ is the volume per unit area of the gate insulating film, and V_{d} is the drain voltage. The film form temperature for amorphous silicon is, for example, 500° C. Also, heat treatment is carried out at, for example, 700° C. for 30 minutes.

μ_{F E} =Gₙ/((W/L)×Cᵢ×V_{d}) (1)

By increasing the phosphorus concentration in the amorphous silicon, the mobility of the polysilicon after recrystallization by heat treatment (it is deemed that amorphous silicon is changed to polysilicon by the heat treatment) increased monotonically, and the threshold level shifted to the negative side monotonically. The reason why mobility becomes high is because, by phosphorus being present in the amorphous silicon, crystallization during heat treatment is encouraged, and the grain diameter of the crystals increases. Due to the increase in the grain diameter of the crystals, the scattering of electrons is suppressed. Also, the reason why the threshold level shifts to the negative side is, due to the increase in the phosphorus concentration, it becomes easier for a channel to be formed in the channel layer.

It has been confirmed through observation with a transmission electron microscope that when the grain diameter of the silicon starts to notably increase in the amorphous silicon, the phosphorus concentration is higher than 6×10¹⁹/cm³. Therefore, when silicon, which is an amorphous silicon transformed into polysilicon, is used for the memory channel layer 20 of the memory cell MC, amorphous silicon is formed in the memory hole MH so that more than 6×10¹⁹/cm³ of phosphorus is included in the polysilicon.

However, if the phosphorus concentration is too high, the threshold level of the memory cell MC becomes too low and the memory cell MC generates a malfunction, so polysilicon with a high phosphorus concentration cannot be used for the memory channel layer 20 as is. Therefore, in the non-volatile semiconductor storage device according to the present embodiment, silicon germanium (henceforth SiGe) that includes phosphorus is used instead of polysilicon and phosphorus for the memory channel layer 20 of the memory cell MC.

FIG. 4 shows one example of germanium (Ge) concentration dependency of the hole concentration in an undoped SiGe. The hole concentration also changes greatly according to the film forming conditions, etc., of SiGe. It can be seen from FIG. 4 that, as the concentration of Ge in SiGe increases, the hole concentration increases. Due to this, even when recrystallization is encouraged by increasing the phosphorus concentration in SiGe and the grain diameter is enlarged, the increase in electrons due to the increase in the phosphorus concentration can be offset by the increase in the Ge concentration in the SiGe. As a result, even if the phosphorus concentration is increased in the SiGe layer, the shift to the negative side of the threshold level of the gate voltage can be suppressed.

In the non-volatile semiconductor storage device according to the present embodiment, since SiGe that includes phosphorus is used for the memory channel layer 20 of the memory string MS, the shift to the negative side of the threshold level of the gate voltage of the memory cell MC can be suppressed while reducing the resistance value of the memory channel layer 20. For this reason, since it becomes possible to increase the number of memory cells MC that are serially-connected in the memory string MS, it becomes possible to further increase the bit density. As with amorphous silicon, the point when the grain diameter starts to notably increase due to recrystallization by heat processing of SiGe in an amorphous state, correlates to when the phosphorus concentration is higher than 6×10¹⁹/cm³. Therefore, when using SiGe for the memory channel layer 20 of the memory string MS, the phosphorus concentration in the SiGe should be greater than 6×10¹⁹/cm³.

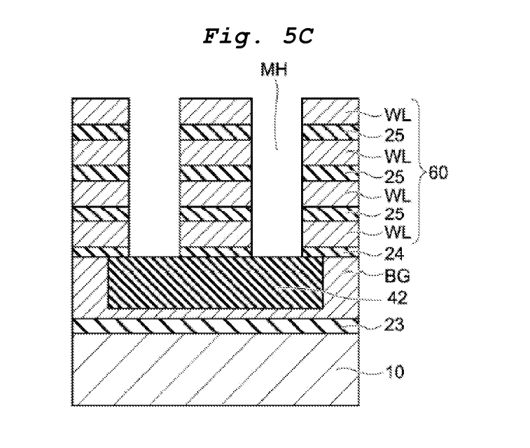

Next a manufacturing method for the non-volatile semiconductor storage device according to one embodiment is described with reference to FIGS. 5A to 8B. FIGS. 5A to 8B are schematic cross-sectional diagrams that show portions of the manufacturing process of the non-volatile semiconductor storage device according to the first embodiment. Additionally, the cross-sectional drawings and the manufacturing process show only the U-shaped memory string MS portion and the other portions are omitted as common memory cell array structures that use bit lines, source lines, select gate lines, and word lines, etc. can be used.

As shown in FIG. 5A, an interlayer dielectric film 23 is formed on a substrate 10, and a depression 41 is formed on the surface of the back gate layer BG that is formed on the interlayer dielectric film 23 using the RIE (Reactive Ion Etching) method. The RIE method utilizes a mask not shown in the drawing. The depression 41 is arranged along the X-direction separated by a distance that is the corresponds with the number of memory strings MS (shown in FIG. 1). The back gate BG is formed of conductive polysilicon.

As shown in the FIG. 5B, a SiN layer 42 is deposited in the depression 41 by the CVD method. The SiN layer 42 is planarized using a CMP (Chemical Mechanical Polishing) method, and the surface of the back gate layer BG and the SiN layer 42 are exposed on the same plane.

Next, as shown in the FIG. 5C, on the back gate layer BG and SiN layer 42, a laminate 60 (stacked film structure) which includes alternative layering of insulating layers 25 and conductive layers WL multiple times, is formed on an interlayer dielectric film 24. The interlayer dielectric films 24 and 25 are silicon dioxide, and the conductive layer WL is a conductive polysilicon. The interlayer dielectric film 23 and interlayer dielectric film 25 are not limited to silicon dioxide, and can be mutually different insulators. They are formed by, for example, the CVD method. A pair of memory holes MH that are adjacent in the Y-direction (laterally) are formed by the RIE method using a mask not shown in the figure. The memory holes MH are formed so that they penetrate the laminate 60 from the surface of the uppermost conductive line WL in the uppermost layer of the laminate 60, and extend to the SiN layer 42. The pair of memory holes MH is formed along the Y-direction so that multiple pairs are spaced apart and are similarly formed so that each will reach one end of the SiN layer 42 formed in the Y-direction in the back gate layer BG. Meanwhile, in the present embodiment, an example where the laminate 60 has a conductive layer WL as the uppermost layer is described, but the laminate 60 including an insulating layer 25 as the uppermost layer is, also, of course, possible. In that example, the process only needs to be partially changed so that it accommodates the insulating layer 25 as the uppermost layer of the laminate 60 later in the manufacturing process.

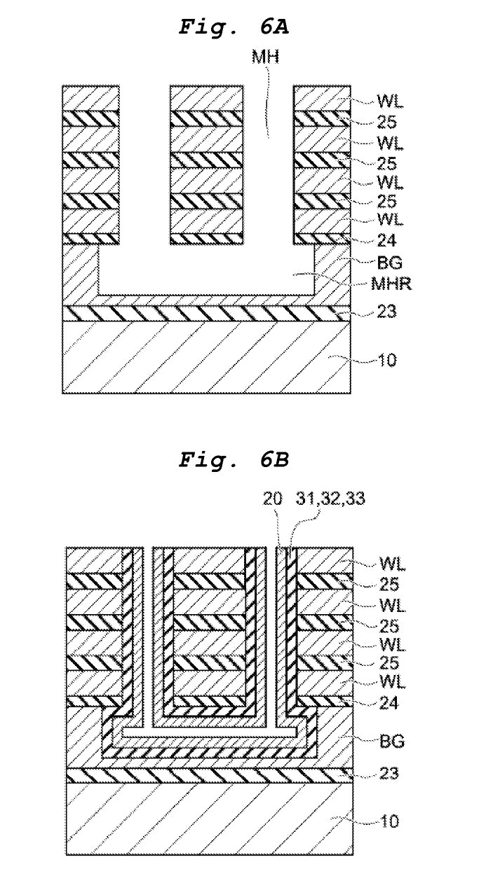

Next, as shown in FIG. 6A, the SiN layer 42 is removed by, for example, wet etching. As a result, the pair of memory holes MH is coupled by a coupling hole region MHR that is formed by the removal of the SiN in the back gate layer BG and becomes a U-shaped hole.

Next, as shown in the FIG. 6B, the first insulating layer 31 is formed along the inner circumference on the inner wall of the U-shaped memory hole MH and so that it extends along the direction (Z-direction) of the laminate 60. That is, the first insulating layer 31 is formed so that it covers the inner wall of the memory hole MH. The first insulating layer 31 is formed so that it covers all of the multiple conductive layers WL and multiple insulating layers 25 that are exposed on the inner wall of the memory hole MH. The first insulating layer 31 is further formed so that it covers the entire inner wall of the coupling hole region MHR and covers the entire surface of the inner wall of the U-shaped hole. The first insulating layer 31 is, for example, a silicon dioxide that is formed by the CVD method.

Next, the charge accumulation layer 32 is formed in the memory hole MH so that it extends along the inner circumference on the inner wall of the first insulating layer 31 and along the Z-direction. That is, the charge accumulation layer 32 is formed so that it covers the first insulating layer 31, and covers all of the multiple conductive layers WL and multiple insulating layers 25 that are exposed on the inner wall in the memory hole MH, via the first insulating layer 31. The charge accumulation layer 32 is further formed in the coupling hole region MHR so that is covers all of the first insulating layer 31, and in the U-shaped hole, covers the entire surface of the first insulating layer 31. The charge accumulation layer 32 is, for example, a SiN formed by the CVD method.

Next, the second insulating layer 33 is formed in the memory hole MH so that it extends along the inner circumference on the inner wall of the charge accumulation layer 32 and along the Z-direction. That is, the second insulating layer 33 is formed so that it covers the charge accumulation layer 32, and covers all of the multiple conductive layers WL and multiple insulating layers 25 that are exposed on the inner wall in the memory hole MH, via the first insulating layer 31 and the charge accumulation layer 32. The second insulating layer 33 is further formed so that, in the coupling hole region MHR, it covers the entire charge accumulation layer 32, and in the U-shaped hole, it covers the entire surface of the charge accumulation layer 32. The second insulating layer 33 is, for example, a silicon dioxide formed by the CVD method.

In the figures after FIG. 6B, the first insulating layer 31, the charge accumulation layer 32, and the second insulating layer 33 are abbreviated and shown as a single layer, but their detailed laminate structures are as shown in FIG. 2.

Next, the memory channel layer 20 is formed in the memory hole MH so that it extends along the inner circumference on the inner wall of the second insulating layer 33 and along the Z-direction. That is, the memory channel layer 20 is formed so that it covers the second insulating layer 33, and covers all of the multiple conductive layers WL and multiple insulating layers 25 that are exposed on the inner wall in the memory hole MH, via the first insulating layer 31, the charge accumulation layer 32, and the second insulating layer 33. The charge memory channel layer 20 is further formed in the coupling hole region MHR so that is covers all of the second insulating layer 33, and in the U-shaped hole, covers the entire surface of the second insulating layer 33. The memory channel layer 20 is, for example, SiGe including phosphorus that is formed by the CVD method.

The memory channel layer 20 is formed in the U-shaped hole with an even thickness. For that reason, the memory channel layer 20 is formed from SiGe in an amorphous state which has a higher degree of flatness than SiGe in a polycrystalline state. By lowering the growth temperature, SiGe is film formed in the amorphous state. For example, with the CVD method with a growth temperature of 500° C., SiGe is film formed in an amorphous state. With the memory channel layer 20 being formed from SiGe in an amorphous state, blocking in the middle of the U-shaped hole is reduced. However, the memory channel layer 20 is not limited to this and can be formed from polycrystalline SiGe.

After that, by providing heat treatment at a temperature that is greater than the growth temperature, for example, at 1050° C. for 30 seconds, recrystallization of SiGe in the memory channel layer 20 is carried out. With this recrystallization, the grain diameter of the crystal grains is enlarged, and mobility improves. Also, when SiGe is in an amorphous state, recrystallization is encouraged by including phosphorus, and it becomes easier to grow the size of the crystal grains with heat treatment after film forming.

SiGe can be film formed in an amorphous state, and the film may be formed with SiGe doped with phosphorus. For this reason, in the manufacturing method of the present embodiment, the memory channel layer 20 is formed by film forming the SiGe in an amorphous state that includes phosphorus. The ingredient for phosphorus is, for example, phosphine (PH₃), when film-forming the SiGe using a CVD method.

The higher the phosphorus concentration in the SiGe, the greater the electron mobility will be due to recrystallization of SiGe, but as the electron concentration in the SiGe becomes high, the threshold level in the memory cell shifts to the negative side. In order to suppress this, the hole concentration is increased by increasing the germanium concentration in the SiGe to compensate for the increase in the electron concentration. That is, according to the design of the resistance value of the memory channel layer 20, the germanium concentration and the phosphorus concentration in the SiGe are set.

After that, SiGe is polycrystallized by heat treatment at a temperature that is higher than the film forming temperature, as described above. By doing it this way, the memory channel layer 20 is formed in the memory hole while including an even thickness and a high electron mobility.

The heat treatment can be carried out in the same chamber in which the SiGe is film formed, immediately after forming the SiGe film. The heat treatment can also be carried out in another chamber. Also, the heat treatment can be carried out after other processes performed subsequent to forming the SiGe film.

Meanwhile in the present embodiment, the memory channel layer is formed by film forming the SiGe that includes phosphorus in an amorphous state by the CVD method. However, the memory channel layer 20 can also be obtained by film forming undoped SiGe in an amorphous state as well. In this case, immediately after film forming the SiGe, in the state shown in FIG. 6B, by carrying out heat treatment in, for example, a phosphine (PH₃) gas atmosphere, phosphorus is disposed on the surface of the memory channel layer 20 from the cavity of the memory hole MH (in the void formed between the memory channel layers 20). With this, the memory channel layer 20 becomes a SiGe film that includes phosphorus. After that, as described above, by carrying out heat treatment, recrystallization of the SiGe occurs and the memory channel layer 20 will include a high electron mobility.

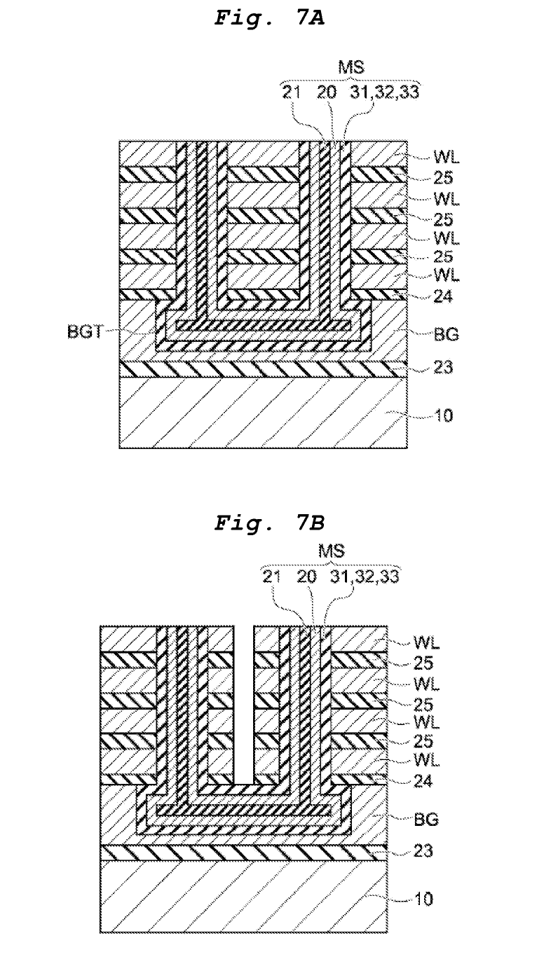

Next, as shown in FIG. 7A, a SiN layer 21 is formed as the center layers in the memory holes MH, so that it extends along the inner circumference on the inner wall of the memory channel layer 20 and along the Z-direction. That is, the SiN layer 21 is formed in the memory hole MH so that it embeds in the void of the memory channel layer 20. Furthermore, the SiN 21 layer is formed along the inner circumference on the inner wall of the memory channel layer 20 in the coupling hole region MHR. That is, across the entirety of the U-shaped hole, the SiN layer 21 is formed in the interior of the memory channel layer 20 as the center layer. The SiN layer 21 is formed, for example, by the CVD method. It is also possible to form a material other than SiN as the center layer.

Alternatively, as shown in FIG. 6B, it is also possible to keep the interior of the memory channel layer 20 as a cavity without forming the SiN layer 21 as the center layer as shown in FIG. 7A. Alternatively, when the memory channel layer 20 is formed by the CVD method, SiGe can be film formed so that the inside of the memory hole MH will not include a cavity and such that the volume between layers 31, 32 and 33 is completely filled-in by the memory channel layer 20.

Next, as shown in FIG. 7B, a trench is formed between the pair of memory holes MH so as to separate the laminate 60. This trench is, for example, formed by the RIE method. The trench is formed so that it penetrates each of the multiple conductive layers WL from the surface of the conductive layer WL in the uppermost layer in the laminate 60. As a result, the laminate 60 is divided into a first block of the laminate 60 that includes one of the pair of memory holes MH, and a second block of the laminate 60 that includes the other of the pair of memory holes MH.

With the process above, as shown by the dashed line in FIG. 2, the memory cell MC is formed by a conductive layer WL, and a first insulating layer 31, a charge accumulation layer 32, a second insulating layer 33, and a memory channel layer 20 that are each disposed in the memory hole MH. In the memory hole MH of each of the first block and the second block of the laminate 60, a first columnar part and a second columnar part are formed, in which this memory cell MC is electrically connected in series in the Z-direction along the direction of the memory hole MH.

Therefore, the back gate transistor BGT includes a back gate layer BG, and a first insulating layer 31, a charge accumulation layer 32, a second insulating layer 33, and a memory channel layer 20 that are formed in the coupling hole region MHR. By the memory channel layer 20 in this back gate transistor BGT, the first columnar part and the second columnar part are electrically connected at the end of the substrate side 10 and a U-shaped memory string MS is formed.

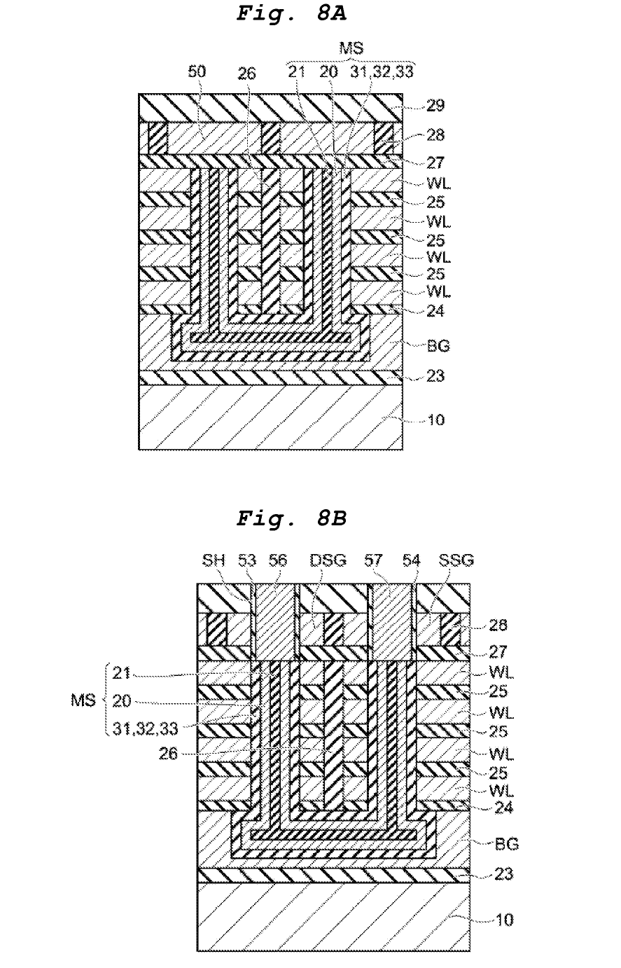

Next, as shown in FIG. 8A, so as to embed the isolation trench that isolates the laminate 60 by dividing it into the first block and the second block, an interlayer dielectric film 26 is film formed on the entire surface of the laminate 60 as well as on the upper end of the memory string MS using, for example, the CVD method. After that, the interlayer dielectric film 26 is planarized until the upper surface of the laminate 60 is exposed using CMP. As a result, the first block and the second block of the laminate embedded with an interlayer dielectric film 26 are electrically isolated.

Next, an interlayer dielectric film 27 is formed on the upper end of the laminate 60, on the upper end of the U-shaped memory string MS, and on the upper end of the interlayer dielectric film 26 using, for example, the CVD method. After that, a conductive layer 50 is formed on the dielectric film 27 on the conductive layer WL and the memory string MS in the uppermost layer of the laminate 60. The conductive layer 50 is, for example, a conductive polysilicon that is formed by CVD.

Next, a trench that penetrates the conductive layer 50 and divides the conductive layer 50 into multiple parts is formed using, for example, the RIE method. As a result, one part of the divided conductive layer 50 is formed on the upper end of the first columnar part of the memory string MS via the interlayer dielectric film 27 and one part of the divided conductive layer is formed on the upper end of the second columnar part of the memory string MS via the interlayer dielectric film 27. A portion of the divided conductive layer 50 that is formed on the first columnar part becomes the drain side select gate layer DSG (shown in FIG. 1) and a portion of the divided conductive layer 50 that is formed on the second columnar part becomes the source side select gate layer SSG (shown in FIG. 1).

An interlayer dielectric film 28 is embedded and formed in the trench between the drain side select gate DSG and the source side select gate layer SSG, in a similar process with which the interlayer dielectric film 26 is formed, and electrically isolates the drain side select gate DSG and the source side select gate layer SSG. After that, an interlayer dielectric film 29 is formed on the drain side select gate DSG, the source side select gate layer SSG, and the interlayer dielectric film 28.

Next, as shown in FIG. 8B, a hole SH is formed so that it penetrates the interlayer dielectric film 29 from the surface of the interlayer dielectric film 29, the drain side select gate DSG or the source side select gate layer SSG, and the interlayer dielectric film 27, and extends to the upper end of the first insulating layer 31 of the memory string MS, the charge accumulation layer 32, the second insulating layer 33, the memory channel layer 20, and the SiN layer 21 by, for example, the RIE method. The diameter of the hole SH is nearly the same as the diameter of the memory hole MH of the first columnar part or the second columnar part of the memory string MS, and in the center of the hole SH is formed concentrically to the center of the memory hole of the first columnar part or the second columnar part in the Z-direction. The diameter of the hole SH is only one example, and it does not necessarily have to be the same diameter as the first columnar part or the second columnar part, but can be made an arbitrary diameter according to changes in the manufacturing process.

Meanwhile, the interlayer dielectric film 26, 27, 28, and 29 can be any insulator, for example, silicon dioxide. Otherwise, silicon nitride or silicon oxynitride can be used as well. The interlayer dielectric film 26, 27, 28, and 29 do not each have to be the same insulator and, depending on cases when the selectivity of etching is necessary, they can each be freely chosen.

Next, gate insulating films 53 and 54 are formed on the interlayer dielectric film 27 that is exposed on the side wall of this hole, the drain side select gate DSG or source side select gate layer SSG, and on the interlayer dielectric film 29. The gate insulating films 53 and 54, in the basal part of the hole SH, are connected to at least the first insulating layer 31. The gate insulating films 53 and 54 can be formed by, after forming an insulating film on the interlayer dielectric film 29 on the side wall and on the bottom surface of the hole SH using CVD, by etching the insulating film on the bottom surface of the interlayer dielectric film 29 and the hole SH using RIE as much as it is film formed. The gate insulating films 53 and 54 are, for example, silicon dioxide but, as with the other insulating films, can be made a silicon oxynitride, silicon nitride, alumina, or other derivatives.

Next, channel layers 56 and 57 are formed in the hole SH via the gate insulating film 53 and 54. The channel layers 56 and 57 include, for example, conductive polysilicon. The channel layers 56 and 57 can be formed by forming polysilicon on the entire surface of the interlayer dielectric film 29 so as to embed the hole SH using the CVD method, after which, by flattening the polysilicon surface until the interlayer dielectric film 29 is exposed by CMP, etc. The channel layers 56 and 57 are electrically connected to the first columnar part or the second columnar part of the memory string MS at the bottom part of the hole SH. That is, the channel layers 56 and 57 are electrically connected to the memory channel layer 20 of the first columnar part or the second columnar part. Also, the memory channels 56 and 57 are insulated from the conductive layer WL in the uppermost layer of the laminate 60 by the gate insulating films 53 and 54.

As a result of the above, the drain side select transistor DST (shown in FIG. 1) includes a channel layer 56, a gate insulating film 53, and a drain side select gate DSG. Also, the source side select transistor SST (shown in FIG. 1) includes a channel layer 57, a gate insulating film 54, and a source side select gate layer SSG. While a detailed description is omitted, the channel layer 56 of the drain side select transistor DST is electrically connected to the bit line BL, and the source side select transistor SST is electrically connected to the source line SL with a later process.

### Second Embodiment

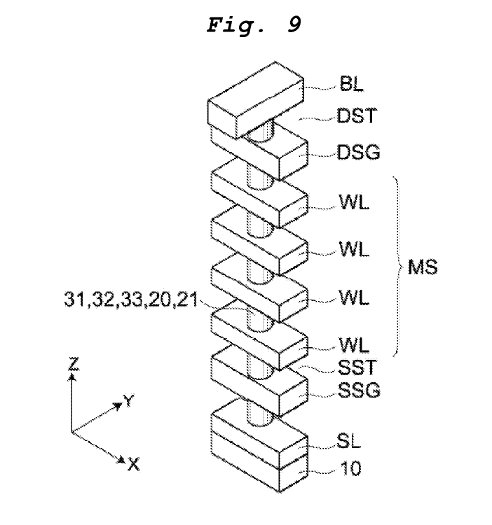

The non-volatile semiconductor storage device according to the second embodiment is described with reference to FIG. 9. FIG. 9 is a schematic diagram that shows the main components of the non-volatile semiconductor storage device according to the second embodiment. Meanwhile, the components that have configurations that are the same as the configurations described for the first embodiment will use the same reference numbers or symbols, and their descriptions will be omitted for brevity. The primary differences between the first embodiment and the second embodiment will be described.

As shown in FIG. 9, the non-volatile semiconductor storage device according to the present embodiment, unlike the U-shaped memory string MS of the first embodiment, includes an I-shaped (linear) memory string MS. That is, the memory string MS according to the present embodiment includes only the first columnar part of the memory string according to the first embodiment.

With the non-volatile semiconductor storage device according to the present embodiment, as with the non-volatile semiconductor storage device according to the first embodiment, one end of the channel layer of the drain side select transistor DST is electrically connected to one end of the memory channel layer 20 of the columnar part of the memory string MS. The other end of the channel layer of the drain side select transistor DST is electrically connected to the bit line BL. The other end of the memory channel layer 20 of the columnar part of the memory string MS is electrically connected, not to the back gate transistor BST, but to one end of the channel layer of the source side select transistor SST. The other end of the channel layer of the source side select transistor SST is electrically connected to the source line SL that is provided on the substrate 10. On this point, the non-volatile semiconductor storage device according to the present embodiment is different from the non-volatile semiconductor storage device according to the first embodiment.

In the non-volatile semiconductor storage device according to the present embodiment, the source side select transistor SST is arranged on the substrate 10. The drain side select transistor DST is positioned on the source side select transistor SST via a memory string that includes only a columnar part. This drain side select transistor DST, a memory string MS and a source side select transistor SST are arranged on the substrate in a lattice form, and the memory cell array of the non-volatile semiconductor storage device according to the present embodiment is formed.

The source side select gate layer SSG of the source side select transistor SST is provided on the substrate 10 and the source line SL on an interlayer dielectric film that is not shown in the figure. The laminate 60 that includes multiple conductive layers WL and multiple insulating layers 25 that make up the columnar part (not shown in FIG. 9) is provided on the source side select gate layer SSG on an interlayer dielectric film that is not shown in the figure. The drain side select gate DSG of the drain side select transistor DST is formed on the laminate 60 on an interlayer dielectric film that is not shown in the figure. The bit line BL is formed on the drain side select gate DSG on an interlayer dielectric film that is not shown in the figure.

In the non-volatile semiconductor storage device according to the present embodiment, as with the non-volatile semiconductor storage device according to the first embodiment, it uses SiGe that includes phosphorus in the memory channel layer 20 of the memory string MS. According to the present embodiment, the shifting of the threshold level of the gate voltage of the memory cell MC to the negative side can be suppressed. Additionally, a decrease in the resistance value of the memory channel layer 20 is achieved. For this reason, since it becomes possible to increase the number of memory cells MC that are series-connected in the memory string MS, it becomes possible to further increase the bit density.

While certain embodiments have been described, these embodiments have been presented by way of example only and are not intended to limit the scope of the invention. Indeed, the novel embodiment described herein may be embodied in a variety of other forms and, furthermore, various omissions, substitutions and changes in the form of the embodiment described herein may be made without departing from the spirit of the invention. The accompanying claims and their equivalents are intended to cover such forms or modifications as would fall within the scope and spirit of the invention.

Embodiments of the present invention can have configurations as those described in the appendixes below.

While certain embodiments have been described, these embodiments have been presented by way of example only, and are not intended to limit the scope of the invention. Indeed, the novel embodiments described herein may be embodied in a variety of other forms. Furthermore, various omissions, substitutions and changes in the form of the embodiments described herein may be made without departing from the spirit of the invention. The accompanying claims and their equivalents are intended to cover such forms or modifications as would fall within the scope and spirit of the inventions.

What is claimed is:

1. A non-volatile semiconductor storage device comprising:
a memory cell array formed on a substrate in a lattice form that includes at least one memory string;
a first select transistor, and
a second select transistor, wherein:
the first select transistor is electrically connected to a first end of the memory string, and the second select transistor is electrically connected to a second end of the memory string;
the at least one memory string includes a columnar portion extending in a first direction that is orthogonal to a plane of the substrate, and a plurality of memory cells are formed in the columnar portion by multiple conductive layers alternating with multiple insulating layers;
a first insulating layer is formed on the memory cells in the first direction;
a charge accumulation layer is formed on the first insulating layer in the first direction;
a second insulating layer is formed on the charge accumulation layer in the first direction; and
a memory channel layer comprising silicon germanium doped with phosphorus is formed on the second insulating layer in the first direction.

2. The non-volatile semiconductor storage device of claim 1, wherein the phosphorus concentration in the memory channel layer is greater than or equal to 6×10¹⁹/cm³.

3. The non-volatile semiconductor storage device of claim 2, wherein:
the insulating layer comprises silicon dioxide;
the charge accumulation layer comprises silicon nitride; and
the second insulating layer comprises silicon dioxide.

4. The non-volatile semiconductor storage device of claim 2, wherein the at least one memory string comprises a first memory string having a first columnar portion including a first plurality of memory cells and a second memory string comprising a second columnar portion having a second plurality of memory cells that is disposed on the substrate opposing the first columnar portion and is electrically connected in series to the first columnar portion.

5. The non-volatile semiconductor storage device of claim 4, wherein the second columnar portion comprises alternately layered conductive layers and insulating layers that are formed on the substrate along the first direction to form the second plurality of memory cells.

6. The non-volatile semiconductor storage device of claim 5, wherein the second columnar portion comprises:
a first insulating layer formed on the memory cells in the first direction;
a charge accumulation layer formed on the first insulating layer in the first direction;
a second insulating layer formed on the charge accumulation layer in the first direction; and
a memory channel layer comprising silicon germanium doped with phosphorus formed on the second insulating layer in the first direction.

7. The non-volatile semiconductor storage device of claim 1, wherein the memory channel layer further includes a silicon nitride layer that extends in the first direction.

8. The non-volatile semiconductor storage device of claim 7, wherein the phosphorus concentration in the memory channel layer is greater than or equal to 6×10¹⁹/cm³.

9. The non-volatile semiconductor storage device of claim 1, wherein the memory channel layer includes an internal cavity that extends in the first direction.

10. The non-volatile semiconductor storage device of claim 9, wherein the phosphorus concentration in the memory channel layer is greater than or equal to 6×10¹⁹/cm³.

11. A non-volatile semiconductor storage device comprising a memory cell array formed on a substrate, the memory cell array having a plurality of memory strings, each of the plurality of memory strings including:
a columnar portion having a plurality of memory cells that can electrically read and write memory that is electrically connected in series along a first direction that is orthogonal to a plane of the substrate;
a first select transistor which includes a first channel layer that is controlled by a first select gate, and an end of the first channel layer is electrically connected to a first end of the memory string;
a second select transistor which includes a second channel layer that is controlled by a second select gate, and an end of the second channel layer is electrically connected to a second end of the memory string along the first direction;
a columnar portion formed along the first direction, the columnar portion comprising a plurality of conductive films and a plurality of insulating films alternately layered with the plurality of conductive films;
a first insulating layer formed along the first direction on an inner wall of a memory hole that is disposed on the plurality of conductive films and the plurality of insulating films;
a charge accumulation layer that is formed along the first direction on an inner wall of the first insulating layer;
a second insulating layer that is formed along the first direction on an inner wall of the charge accumulation layer; and
a memory channel layer that is formed along the first direction on an inner wall of the second insulating layer, wherein the memory channel layer comprises silicon germanium doped with phosphorus.

12. The non-volatile semiconductor storage device of claim 11, wherein the phosphorus concentration in the memory channel layer is greater than or equal to 6×10¹⁹/cm³.

13. The non-volatile semiconductor storage device of claim 11, wherein the memory channel layer further includes a silicon nitride layer that extends in the first direction.

14. The non-volatile semiconductor storage device of claim 11, wherein the memory channel layer includes an internal cavity that extends in the first direction.

15. A manufacturing method for a non-volatile semiconductor storage device, comprising:
forming a plurality of conductive layers and a plurality of insulating layers alternating with the plurality of conductive layers on a substrate in a first direction that is perpendicular to a principle plane of the substrate;
forming a memory hole that is exposed to the plurality of conductive layers and the plurality of insulating layers;
forming a first insulating layer on a inner wall of the memory hole, to cover the inner wall of the memory hole and extend along the first direction;
forming a charge accumulation layer on the first insulating layer that extends along the first direction;
forming a second insulating layer on the charge accumulation layer that extends along the first direction; and
forming a memory channel layer on the second insulating layer and extends along the first direction, the memory channel layer comprising silicon and germanium doped with phosphorus.

16. The method of claim 15, wherein forming the memory channel layer comprises:
growing a silicon germanium layer from a vapor on the second insulating layer at a first temperature while doping the second insulating layer with phosphorus from a phosphorus source.

17. The method of claim 16, wherein the phosphorus source comprises phosphine.

18. The method of claim 16, wherein forming the memory channel layer further comprises:
heat treating the silicon germanium layer at a second temperature that is greater than the first temperature, subsequent to the growing of the silicon germanium layer.

19. The method of claim 15, further comprising:
forming a first select transistor that includes a first channel layer that is controlled by a first select gate, wherein an end of the first channel layer is electrically connected to a first end of the memory channel layer; and
forming a second select transistor that includes a second channel layer that is controlled by a second select gate, wherein an end of the second channel layer is electrically connect to a second end of the memory channel layer opposing the first end.

20. The method of claim 19, wherein the phosphorus concentration in the memory channel layer is greater than or equal to 6×10¹⁹/cm³.
